(19) United States
(12) Patent Application Publication
(10) Pub. No.: US 2025/0062157 A1
(43) Pub. Date: Feb. 20, 2025

(54) Shallow Trench Isolation using Porous Semiconductor

(71) Applicant: Murata Manufacturing Co., Ltd., Kyoto (JP)

(72) Inventors: Kouassi Sebastien Kouassi, San Diego, CA (US); Sinan Goktepeli, Austin, TX (US)

(21) Appl. No.: 18/451,542

(22) Filed: Aug. 17, 2023

(51) Int. Cl. H01L 21/762; H01L 27/092

(52) U.S. Cl. CPC H01L 21/76224; H01L 27/092

(57) ABSTRACT

Fabrication methods and structures for forming integrated circuit (IC) porous semiconductor (π-Semi) isolation structures such as shallow trench isolation (STI) and/or deep trench isolation (DTI) structures. The methods speed up IC front-end-of-line processing and decrease the cost of IC fabrication. In general, exposed portions of a semiconductor layer are subjected to an electrochemical etching to form π-Semi isolation structures; in essence, the in situ semiconductor is restructured to π-Semi. The characteristics of π-Semi, particularly mesoporous π-Semi and microporous π-Semi, include good electrical insulation as well as hole trapping capability. Accordingly, π-Semi used for STI and/or DTI structures provides excellent electrical isolation. A first embodiment comprises a “pre-FET” π-Semi isolation structure, fabricated before formation of gate, drain, and source structures or regions of a field-effect transistor (FET). A second embodiment comprises a “post-FET” π-Semi isolation structure, fabricated after formation of gate, drain, and source structures or regions of a FET.

### BACKGROUND

### (1) Technical Field

This invention relates to fabrication of semiconductor integrated circuits.

### (2) Background

Shallow trench isolation (STI) is an integrated circuit (IC) feature which prevents electric current leakage between adjacent semiconductor device components. In general, STI structures are created before transistors are formed during the semiconductor device fabrication process (commonly referred to as “front-end-of-line” or FEOL processing). Key steps of a conventional STI process involve etching a pattern of trenches in a silicon layer, depositing one or more dielectric materials (such as silicon dioxide) to fill the trenches, and removing any excess dielectric (e.g., by chemical-mechanical polishing (CMP)). Certain semiconductor fabrication technologies also include deep trench isolation (DTI), a related feature often found in analog integrated circuits, conventionally fabricated with the same “etch and fill” techniques used for STI fabrication.

Speeding up FEOL processing and decreasing the cost of IC fabrication are desirable goals in the semiconductor industry. The present invention is directed to fabrication methods and structures that further these goals.

### SUMMARY

The present invention encompasses fabrication methods and structures for forming integrated circuit (IC) porous semiconductor (π-Semi) isolation structures such as shallow trench isolation (STI) and/or deep trench isolation (DTI) structures. The inventive methods speed up IC front-end-of-line (FEOL) processing and decrease the cost of IC fabrication.

In general, exposed portions of a crystalline semiconductor layer are subjected to an electrochemical etching to form π-Semi isolation structures. In essence, the in situ semiconductor is restructured to π-Semi. The characteristics of π-Semi, particularly mesoporous π-Semi and microporous-Semi, include good electrical insulation as well as hole trapping capability. Accordingly, π-Semi used for STI and/or DTI structures provides excellent electrical isolation.

A first embodiment may be characterized as a “pre-FET” π-Semi isolation structure, fabricated before formation of gate, drain, and source structures or regions of a field-effect transistor (FET). The first embodiment may be fabricated by patterning a layer of semiconductor to define areas of semiconductor where porous semiconductor isolation structures are to be formed, electrochemically etching the defined areas of semiconductor to form porous semiconductor isolation structures, forming a protective cap for the porous semiconductor isolation structures by rearranging or converting the atomic structure of the porous semiconductor near the top of porous semiconductor isolation structure back into crystalline semiconductor, and forming FET structures in and/or on regions of the layer of semiconductor each surrounded by a respective porous semiconductor isolation structure.

A second embodiment may be characterized as a “post-FET” π-Semi isolation structure, fabricated after formation of gate, drain, and source structures or regions of a FET. The second embodiment may be fabricated by forming FET structures in and/or on a layer of semiconductor, forming a protective coating on the formed FET structures to define areas of semiconductor where porous semiconductor isolation structures are to be formed, electrochemically etching the defined areas of semiconductor to form porous semiconductor isolation structures, forming a protective cap for the porous semiconductor isolation structures by rearranging or converting the atomic structure of the porous semiconductor near the top of porous semiconductor isolation structure back into crystalline semiconductor, and removing the protective coating on the formed FET structures.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1A is a first cross-sectional diagram of a first IC structure at an early stage of fabrication.

FIG. 1B is a second cross-sectional diagram of the IC structure of FIG. 1A at a stage of fabrication in which π-Semi isolation structures are formed.

FIG. 1C is a stylized perspective view showing the transformation of crystalline semiconductor into π-Semi having a multitude of pores.

FIG. 1D is a third cross-sectional diagram of the IC structure of FIG. 1A at a stage of fabrication in which the tops of the π-Semi isolation structures are sealed.

FIG. 1E is a fourth cross-sectional diagram of the IC structure of FIG. 1A at a stage of fabrication showing that the pad nitride layer and pad oxide layer are respectively removed.

FIG. 1F is a fifth cross-sectional diagram of the IC structure of FIG. 1A at a further stage of fabrication.

FIG. 1G is a sixth cross-sectional diagram of the IC structure of FIG. 1A at a still further stage of fabrication, showing formed FET structures.

FIG. 1H is a seventh cross-sectional diagram of the IC structure of FIG. 1A at a still further stage of fabrication, showing post-FET formation structures.

FIG. 2A is a first cross-sectional diagram of a second IC structure at an early stage of fabrication.

FIG. 2B is a second cross-sectional diagram of the IC structure of FIG. 2A at a subsequent stage of fabrication.

FIG. 2C is a third cross-sectional diagram of the IC structure of FIG. 2A at a stage of fabrication in which π-Semi isolation structures are formed.

FIG. 2D is a fourth cross-sectional diagram of the IC structure of FIG. 2A at a stage of fabrication in which the tops of the π-Semi isolation structures are sealed.

FIG. 2E is a fifth cross-sectional diagram of the IC structure of FIG. 2A at a further stage of fabrication in which the SAB material has been removed.

FIG. 2F is a sixth cross-sectional diagram of the IC structure of FIG. 2A at a still further stage of fabrication.

FIG. 3 is a perspective view of an N-type FET in isolation (the dimensions of various elements are not to scale).

FIG. 4 is a process flow chart summarizing one method for fabrication of pre-FET π-Semi isolation structures.

FIG. 5 is a process flow chart summarizing one method for fabrication of post-FET π-Semi isolation structures.

FIG. 6 is a top plan view of a substrate that may be, for example, a printed circuit board or chip module substrate (e.g., a thin-film tile).

Like reference numbers and designations in the various drawings indicate like elements unless the context requires otherwise.

### DETAILED DESCRIPTION

The present invention encompasses fabrication methods and structures for forming integrated circuit (IC) porous semiconductor (π-Semi) isolation structures such as shallow trench isolation (STI) and/or deep trench isolation (DTI) structures. The inventive methods speed up IC front-end-of-line (FEOL) processing and decrease the cost of IC fabrication.

The characteristics of π-Semi, particularly mesoporous π-Semi and microporous π-Semi, include good electrical insulation as well as hole trapping capability. Accordingly, π-Semi used for STI and/or DTI structures provides excellent electrical isolation.

A first embodiment may be characterized as a “pre-FET” π-Semi isolation structure, fabricated before formation of gate, drain, and source structures or regions of a field-effect transistor (FET). A second embodiment may be characterized as a “post-FET” π-Semi isolation structure, fabricated after formation of gate, drain, and source structures or regions of a FET.

It may be useful to review how typical metal-oxide-semiconductor FET (MOSFET) circuitry is fabricated using a conventional process. Starting with a wafer substrate, such as bulk silicon, an active layer is formed, typically of doped crystalline silicon. In some embodiments, an electrically insulating layer (e.g., a buried oxide or “BOX” layer) may be interposed between the wafer substrate and the active layer, possibly with an etch-stop material interposed between the insulating layer and the active layer. On and/or within the active layer, one or more MOSFET structures are formed within the bounds of an individual IC die (unsingulated at this point). Each wafer substrate typically includes hundreds to thousands of unsingulated dies.

A MOSFET structure generally includes a mask-formed channel, a gate, a source, a drain, and isolation regions such as STIs and/or DTI's. The IC fabrication process up to this point is generally considered FEOL, where individual devices (transistors, capacitors, resistors, inductors etc.) are patterned in or on the active layer. The FEOL generally covers everything up to (but not including) the deposition of metal interconnect layers, and may be regarded as fabrication of die substructures.

After the last FEOL step, a wafer contains multiple die regions each including isolated transistors without any interconnecting conductors. The back-end-of-line (BEOL) is the second portion of IC fabrication where the individual devices (transistors, capacitors, resistors, inductors, etc.) within a die region are interconnected with conductors formed as part of or spanning one or more metal interconnect layers. BEOL includes fabrication of electrical contacts (pads), vias, insulating layers (dielectrics), metallization layers, and bonding sites for die-to-package connections. In some applications, “through-substrate vias” (TSVs) may be fabricated, each TSV passing through the wafer substrate between the active layer and a connection point, such as a bond pad.

Thus, a MOSFET IC die is essentially formed in two parts, a “lower” FEOL substructure including a substrate and an “upper” BEOL superstructure formed on a substructure. After FEOL and BEOL processing, the wafer may undergo a number of additional process steps, including dicing, testing, and packaging, to form multiple IC dies.

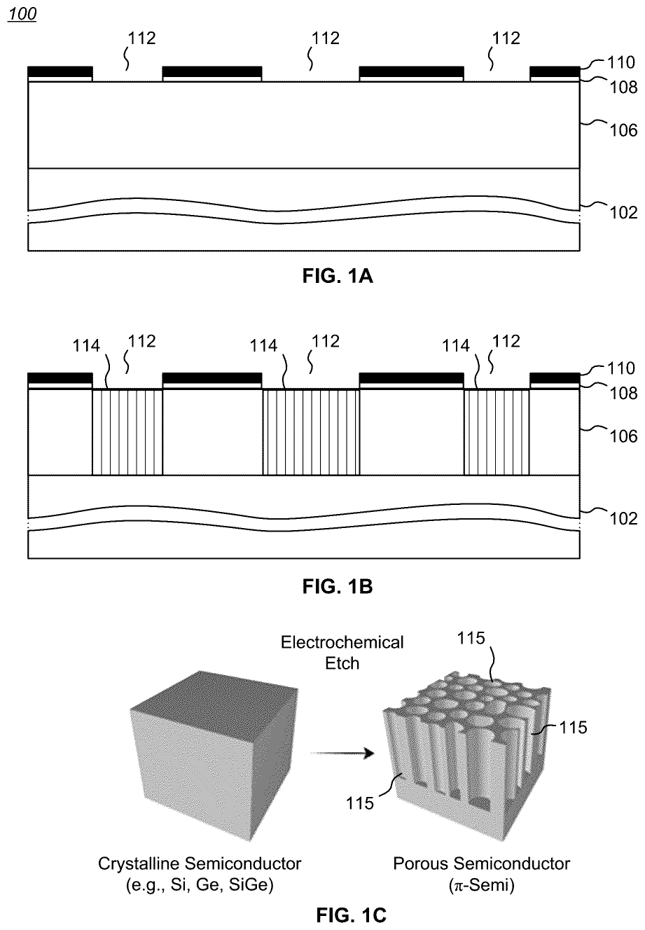

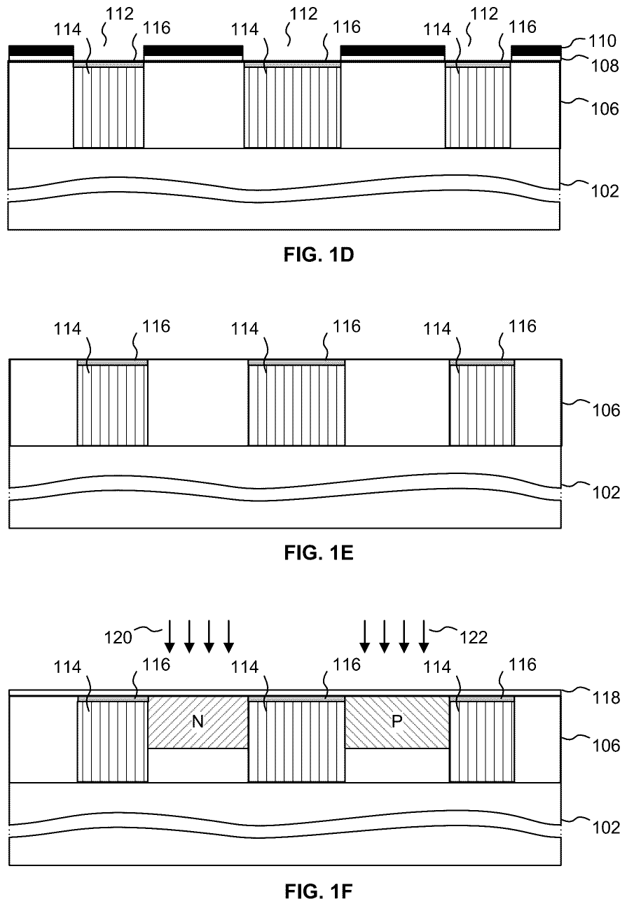

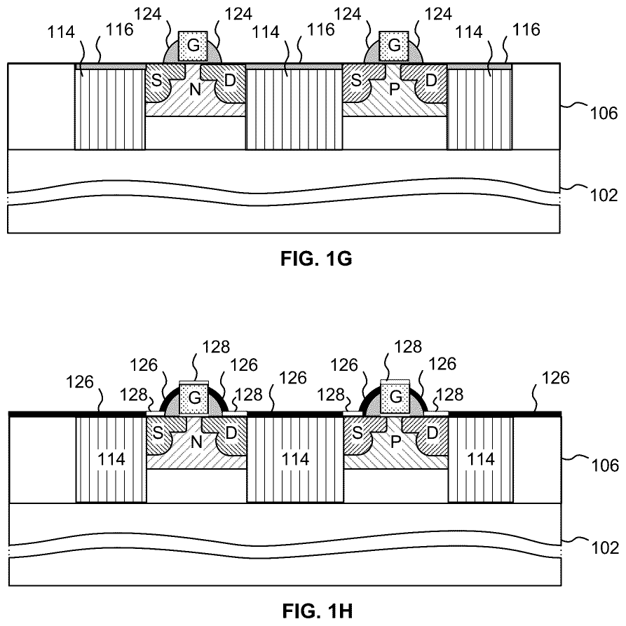

As noted above, a first embodiment may be characterized as a “pre-FET” π-Semi isolation structure. FIG. 1A is a first cross-sectional diagram of a first IC structure 100 at an early stage of fabrication. The foundation of the illustrated IC structure 100 is a substrate 102 that may be any suitable material compatible with MOSFET manufacturing and that can be modified electrochemically to become porous, such as doped or undoped silicon (Si), germanium (Ge), SiGe, III-V group materials, etc. Note that the illustrated substrate 102 is shown with a “broken” section to indicate that the substrate 102 is typically much thicker than the various layers formed on the substrate 102. In the illustrated example, an active layer 106, which may be an epitaxially grown layer of single-crystal semiconductor, is formed on top of the substrate 102.

A pad oxide layer 108 composed of SiO₂ is formed on the active layer 106, such as by thermal oxidation. A pad nitride layer 110 of silicon nitride (Si₃N₄) is deposited on the pad oxide layer 108, such as by chemical vapor deposition. In the example shown in FIG. 1A, the pad oxide layer 108 and the pad nitride layer 110 have been masked and etched (i.e., patterned) to form openings 112 where π-Semi isolation structures are to be formed.

Conventionally, at this stage, the pad nitride layer 110 and the exposed active layer 106 within the defined openings 112 would be etched to form trenches and then the trenches would be filled with a dielectric, such as SiO₂. However, in the first embodiment of the inventive process, rather than take the time-consuming steps of etching and filling to form STIs or DTIs, instead the exposed portions of the active layer 106 within the defined openings 112 are transformed into porous semiconductor (π-Semi).

FIG. 1B is a second cross-sectional diagram of the IC structure 100 of FIG. 1A at a stage of fabrication in which π-Semi isolation structures are formed. The exposed portions of the active layer 106 within the defined openings 112 are subjected to an electrochemical etching to form π-Semi isolation structures 114. In essence, the in situ semiconductor within the defined openings 112 is restructured to π-Semi. FIG. 1C is a stylized perspective view showing the transformation of crystalline semiconductor into π-Semi having a multitude of pores 115.

Porous semiconductor may be formed, for example, by anodic dissolution of exposed crystalline semiconductor within the active layer 106 using hydrofluoric acid (HF) based electrolytes, which may include a number of different known additives (e.g., acetic acid, and surfactants or solvents such as ethanol) to control pore size, wettability, and etch rates. The etchant and etching conditions (particularly time and temperature) are preferably selected to form microporous π-Semi (pore diameters φ less than about 2 nm) or mesoporous π-Semi (pore diameters φ between about 2 nm and 50 nm), rather than macroporous π-Semi (pore diameters φ greater than about 50 nm).

In the illustrated example, the π-Semi isolation structures 114 extend from the upper surface of the active layer 106 down to the substrate 102. However, if desired for particular applications, etching may be stopped before the π-Semi isolation structures 114 reach the substrate 102.

FIG. 1D is a third cross-sectional diagram of the IC structure 100 of FIG. 1A at a stage of fabrication in which the tops of the π-Semi isolation structures 114 are sealed. Sealing the tops of the π-Semi isolation structures 114 protects them from contamination in later FEOL stages that might adversely affect the electrical isolation characteristics of those structures. The exposed portions of each π-Semi isolation structure 114 are subjected to a substance, such as argon (Ar) or hydrogen (H₂) gas, that rearranges or converts the atomic structure of the π-Semi near the top of π-Semi isolation structure 114 back into crystalline semiconductor, thereby forming a protective cap 116 of recrystallized semiconductor.

FIG. 1E is a fourth cross-sectional diagram of the IC structure 100 of FIG. 1A at a stage of fabrication showing that the pad nitride layer 110 and pad oxide layer 108 (see FIGS. 1C and 1D) are respectively removed. In some embodiments, only the pad nitride layer 110 may be removed, leaving the pad oxide layer 108 in place.

FIG. 1F is a fifth cross-sectional diagram of the IC structure 100 of FIG. 1A at a further stage of fabrication. In this particular example, a sacrificial oxide layer 118 is formed over the top surface of the IC structure 100, such as by exposure to O₂ if the top surface of the IC structure 100 is silicon. In that case, the top surface of the protective caps 116 as well as the top surface of the adjacent portions of active layer 106 will be transformed to SiO₂ (also known as glass). The IC structure 100 may then be subjected to conventional FEOL steps to form individual FETs within isolated regions each surrounded by a respective π-Semi isolation structure 114. For example, in FIG. 1E, an N-type well and a P-type well may be formed by masking to define areas within surrounding π-Semi isolation structures 114 and implanting suitable dopants 120, 122.

FIG. 1G is a sixth cross-sectional diagram of the IC structure 100 of FIG. 1A at a still further stage of fabrication, showing formed FET structures. The sacrificial oxide layer 118 has been removed, gate structures G have been formed, suitable doping has been applied to form source S and drain D regions (including low doped drain regions underneath the gate structures G), and gate sidewalls 124 have been applied.

FIG. 1H is a seventh cross-sectional diagram of the IC structure 100 of FIG. 1A at a still further stage of fabrication, showing post-FET formation structures. In the illustrated example, silicon nitride protective coatings 126 have been formed over the gate sidewalls 124, π-Semi isolation structures 114, and portions of the active layer 106 outside of the FET structures. In addition, salicide caps 128 to enhance connectivity have been formed on the source S and drain D regions, and on the gate structure G. The result is an N-type FET and a P-type FET that may be connected as a complementary metal-oxide-semiconductor (CMOS) FET pair during subsequent BEOL superstructure processing.

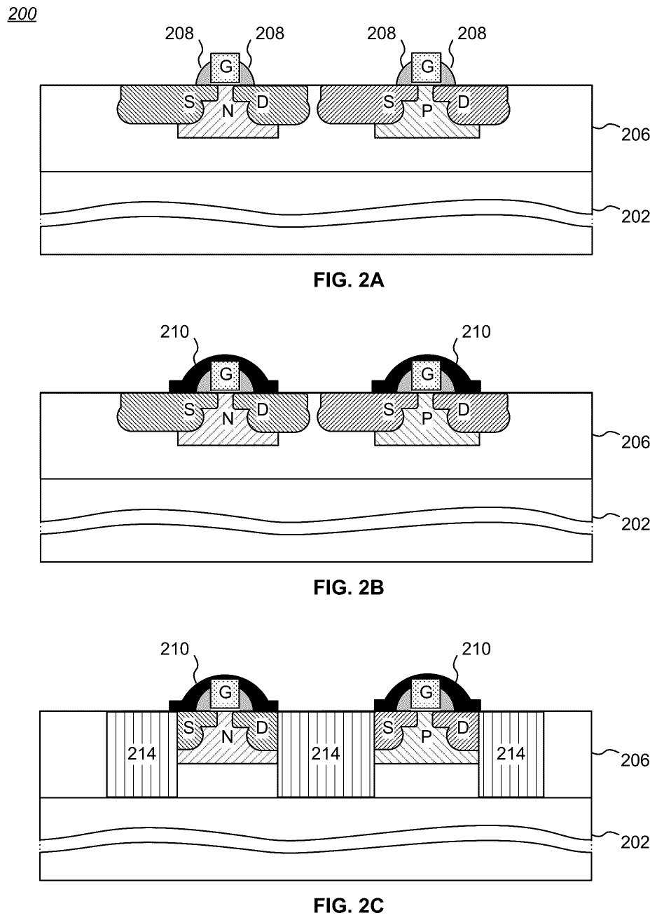

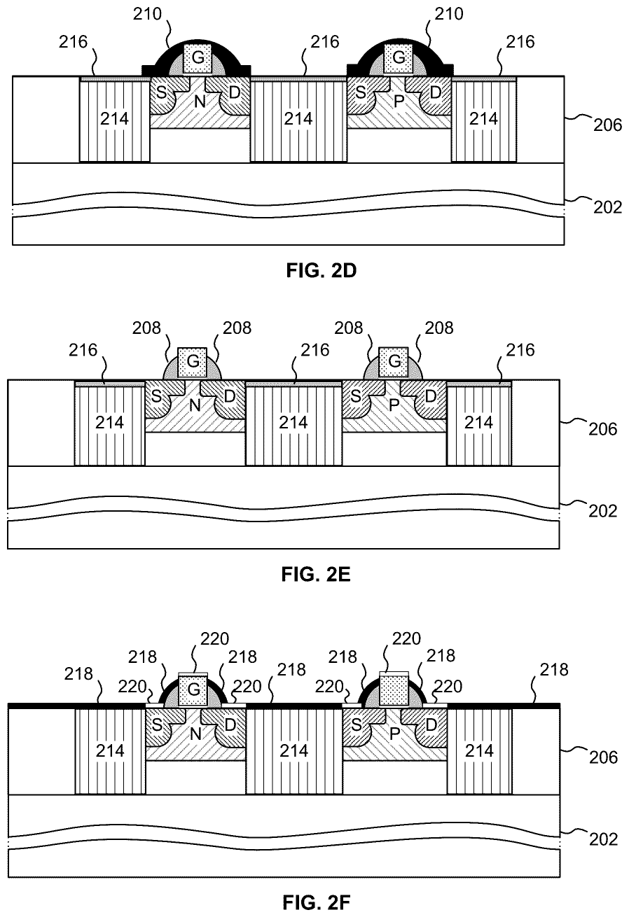

As noted above, a second embodiment may be characterized as a “post-FET” π-Semi isolation structure. FIG. 2A is a first cross-sectional diagram of a second IC structure 200 at an early stage of fabrication. The foundation of the illustrated IC structure 200 is a substrate 202 that may be any suitable material compatible with MOSFET manufacturing and that can be modified electrochemically to become porous. Again note that the illustrated substrate 202 is shown with a “broken” section to indicate that the substrate 202 is typically much thicker than the various layers formed on the substrate 202.

In the illustrated example, an active layer 206 is formed on top of the substrate 202. The IC structure 200 has been subjected to conventional FEOL steps to form an N-type FET and a P-type FET. For example, in FIG. 2A, an N-type well and a P-type well have been formed, respective gate structures G have been formed over the wells, suitable doping has been applied to form source S and drain D regions (including low doped drain regions underneath the gate structures G), and gate sidewalls 208 have been applied.

FIG. 2B is a second cross-sectional diagram of the IC structure 200 of FIG. 2A at a subsequent stage of fabrication. After suitable masking, a protective salicide block (SAB) material 210 (e.g., SiO₂ or SiN) is applied over the gate structures G and portions of the source S and drain D regions adjacent to the gate structures G.

FIG. 2C is a third cross-sectional diagram of the IC structure 200 of FIG. 2A at a stage of fabrication in which π-Semi isolation structures 214 are formed. The exposed portions of the active layer 206 not covered by the SAB material 210 are subjected to an electrochemical etching to form π-Semi isolation structures 214.

FIG. 2D is a fourth cross-sectional diagram of the IC structure 200 of FIG. 2A at a stage of fabrication in which the tops of the π-Semi isolation structures 214 are sealed. The exposed portions of each π-Semi isolation structure 214 is subjected to a substance, such as argon (Ar) or hydrogen (H₂) gas, that rearranges the atomic structure of the π-Semi near the top of π-Semi isolation structure 214 back into crystalline semiconductor, thereby forming a protective cap 216 of recrystallized semiconductor.

FIG. 2E is a fifth cross-sectional diagram of the IC structure 200 of FIG. 2A at a further stage of fabrication in which the SAB material 210 has been removed, such as by a dry etching technique (e.g., O₂ plasma etching or the like).

FIG. 2F is a sixth cross-sectional diagram of the IC structure 200 of FIG. 2A at a still further stage of fabrication. In the illustrated example, silicon nitride protective coatings 218 have been formed over the gate sidewalls 208, π-Semi isolation structures 214, and portions of the active layer 206 outside of the FET structures. In addition, salicide caps 220 to enhance connectivity have been formed on the source S and drain D regions, and on the gate structure G. The result is an N-type FET and a P-type FET that may be connected as a CMOS FET pair during subsequent BEOL superstructure processing.

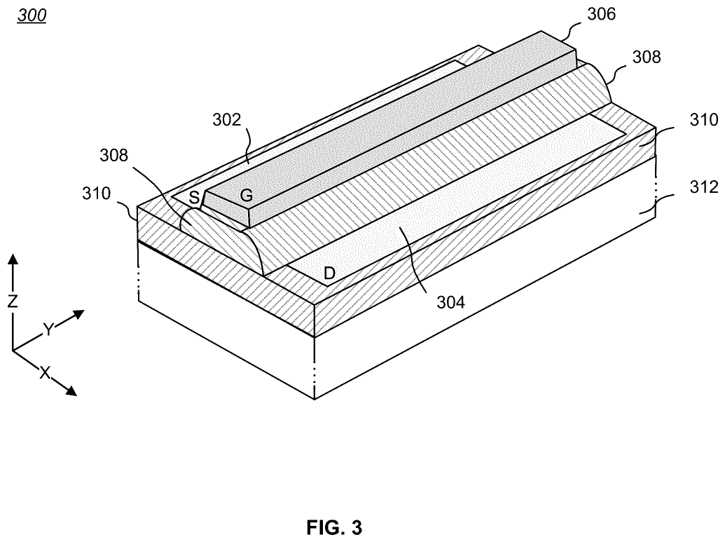

FIGS. 1A-1H and 2A-2F show cross-sectional views of an N-type FET and a P-type FET. It should be appreciated that the illustrated π-Semi isolation structures 114, 214 generally surround each of the N-type and P-type FETs. For example, FIG. 3 is a perspective view of an N-type FET 300 in isolation (the dimensions of various elements are not to scale). A source region 302 and a drain 304 region are located on either side of a gate structure 306 surrounded by gate sidewalls 308. The source region 302, drain 304 region, and gate structure 306 are surrounded by a π-Semi isolation structures 310 made in accordance with the present invention. The FET structure and π-Semi isolation structures 114 are formed on top of a substrate 312. Other common structures (e.g., device interconnects, gate contacts, etc.) are omitted for clarity. The cross-sectional views shown in FIGS. 1A-1H and 2A-2F are along the X-Z plane of FIG. 3.

While the examples shown in FIGS. 1A-1H and 2A-2F have been in the context of an IC architecture, the inventive structures and method may be used with any semiconductor-based IC architecture that might benefit from having π-Semi isolation structures.

It should be appreciated that fabrication of ICs is a multi-step process and manufacturers and foundries typically have their own step sequence and recipes for forming and modifying IC layers and structures. For example, formation of a gate structure alone may involve seven or more fabrication steps. Accordingly, it should be appreciated that the sequence of steps described above for fabricating FET structures using either pre-FET and post-FET fabrication of π-Semi isolation structures may involve many more steps to complete the FEOL process (and of course, the BEOL process is also a multi-step process). However, such steps are generally known in the industry.

Electrochemical wet etching of semiconductor to form π-Semi isolation structures (e.g., 114 in FIG. 1H or 213 in FIG. 2F) is much cheaper than conventional dry etch techniques used for conventional STI structures, and is substantially faster than conventional STI etching, filling, and polishing processes (with deeper DTI processes being slower still)—and time is money in the IC business. Fabricating π-Semi isolation structures in situ also requires fewer steps than conventional STI or DTI processes and reduces strain and stress in the substrate that can be caused by strain/defects at the semiconductor/STI interface.

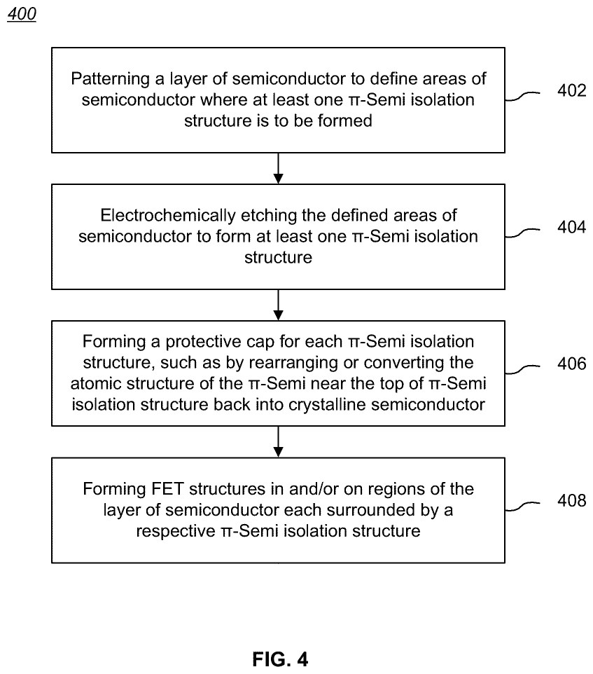

FIG. 4 is a process flow chart 400 summarizing one method for fabrication of pre-FET π-Semi isolation structures. The method includes: patterning a layer of semiconductor to define areas of semiconductor where at least one π-Semi isolation structure is to be formed (Block 402); electrochemically etching the defined areas of semiconductor to form at least one π-Semi isolation structure (Block 404); forming a protective cap for the π-Semi isolation structures, such as by rearranging or converting the atomic structure of the π-Semi near the top of π-Semi isolation structure back into crystalline semiconductor (Block 406); and forming FET structures on and/or within regions of the layer of semiconductor each surrounded by a respective porous semiconductor isolation structure (Block 408).

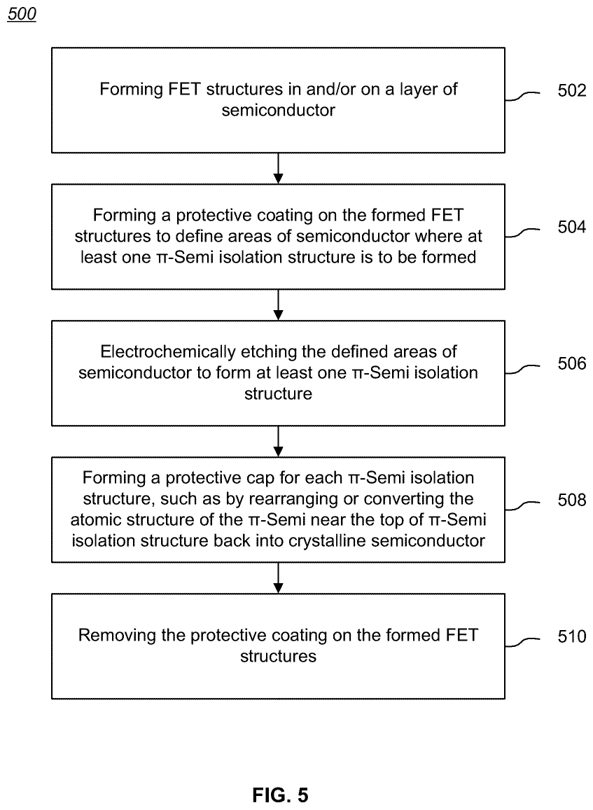

FIG. 5 is a process flow chart 500 summarizing one method for fabrication of post-FET π-Semi isolation structures. The method includes: forming FET structures in and/or on a layer of semiconductor (Block 502); forming a protective coating on the formed FET structures to define areas of semiconductor where π-Semi isolation structures are to be formed (Block 504); electrochemically etching the defined areas of semiconductor to form π-Semi at least one isolation structure (Block 506); forming a protective cap for the π-Semi isolation structures by rearranging or converting the atomic structure of the π-Semi near the top of π-Semi isolation structure back into crystalline semiconductor (Block 508); and removing the protective coating on the formed FET structures (Block 510).

Circuits and devices in accordance with the present invention may be used alone or in combination with other components, circuits, and devices. Embodiments of the present invention may be fabricated as integrated circuits (ICs), which may be encased in IC packages and/or in modules for case of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

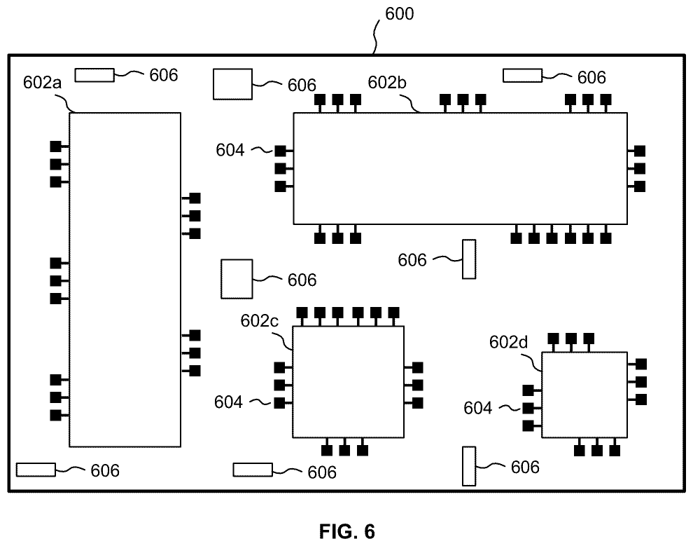

As one example of further integration of embodiments of the present invention with other components, FIG. 6 is a top plan view of a substrate 600 that may be, for example, a printed circuit board or chip module substrate (e.g., a thin-film tile). In the illustrated example, the substrate 600 includes multiple ICs 602a-602d having terminal pads 604 which would be interconnected by conductive vias and/or traces on and/or within the substrate 600 or on the opposite (back) surface of the substrate 600 (to avoid clutter, the surface conductive traces are not shown and not all terminal pads are labelled). The ICs 602a-602d may embody, for example, signal switches, active and/or passive filters, amplifiers (including one or more LNAs), and other circuitry based on FET structures that include π-Semi isolation structures in accordance with the present invention.

The substrate 600 may also include one or more passive devices 606 embedded in, formed on, and/or affixed to the substrate 600. While shown as generic rectangles, the passive devices 606 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 600 to other passive devices 606 and/or the individual ICs 602a-602d. The front or back surface of the substrate 600 may be used as a location for the formation of other structures.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes using 2-D, 2.5-D, and 3-D structures. Monolithic IC implementation is particularly useful since parasitic capacitances generally can be kept low (or at a minimum, kept uniform across all units, permitting them to be compensated) by careful design.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. An integrated circuit including at least one porous semiconductor isolation structure.

2. The invention of claim 1, wherein the at least one porous semiconductor isolation structure includes a protective cap.

3. The invention of claim 1, wherein the at least one porous semiconductor isolation structure includes a protective cap of recrystallized semiconductor.

4. The invention of claim 1, wherein the at least one porous semiconductor isolation structure comprises microporous semiconductor.

5. The invention of claim 1, wherein the at least one porous semiconductor isolation structure comprises mesoporous semiconductor.

6. An integrated circuit including at least one transistor structure surrounded by a porous semiconductor isolation structure.

7. The invention of claim 6, wherein the at least one porous semiconductor isolation structure includes a protective cap.

8. The invention of claim 6, wherein the at least one porous semiconductor isolation structure includes a protective cap of recrystallized semiconductor.

9. The invention of claim 6, wherein the at least one porous semiconductor isolation structure comprises microporous semiconductor.

10. The invention of claim 6, wherein the at least one porous semiconductor isolation structure comprises mesoporous semiconductor.

11. A method of forming integrated circuit porous semiconductor isolation structures, including:
(a) patterning a layer of semiconductor to define areas of semiconductor where at least one porous semiconductor isolation structure is to be formed;
(b) forming at least one porous semiconductor isolation structure within the defined areas of semiconductor;
(c) forming a protective cap for each porous semiconductor isolation structure; and
(d) forming transistor structures in and/or on regions of the layer of semiconductor each surrounded by a respective porous semiconductor isolation structure.

12. The method of claim 11, wherein forming the protective cap for the at least one porous semiconductor isolation structure includes rearranging or converting the atomic structure of the porous semiconductor near the top of porous semiconductor isolation structure into crystalline semiconductor.

13. The method of claim 11, wherein forming at least one porous semiconductor isolation structure is by electrochemically etching the defined areas of semiconductor.

14. The method of claim 13, wherein electrochemically etching the defined areas of semiconductor is by anodic dissolution of crystalline semiconductor within the defined areas of semiconductor.

15. The method of claim 13, wherein electrochemically etching the defined areas of semiconductor is by anodic dissolution of crystalline semiconductor within the defined areas of semiconductor using hydrofluoric acid based electrolytes.

16. The method of claim 11, wherein the at least one porous semiconductor isolation structure comprises microporous semiconductor.

17. The method of claim 11, wherein the at least one porous semiconductor isolation structure comprises mesoporous semiconductor.

18.-39. (canceled)
